(19) United States
(12) Patent Application Publication
(10) Pub. No.: US 2017/0005119 A1
(43) Pub. Date: Jan. 5, 2017

(54) MANUFACTURING METHOD OF THIN FILM TRANSISTOR SUBSTRATE

(71) Applicant: Samsung Display Co., Ltd., Yongin-Si (KR)

(72) Inventors: Minjung Kang, Yongin-si (KR); Daeyoun Park, Yongin-si (KR); Nuree Um, Yongin-si (KR)

(21) Appl. No.: 14/923,656

(22) Filed: Oct. 27, 2015

(30) Foreign Application Priority Data
Jul. 3, 2015 (KR) 10-2015-0095279

(51) Int. Cl. H01L 27/12; H01L 29/786

(52) U.S. Cl. CPC H01L 27/1288; H01L 29/7869; H01L 27/124; H01L 27/1225

(57) ABSTRACT

A manufacturing method of a thin film transistor substrate includes providing a plurality of pixels each having a display region in which color and a non-display region that is outside the display region on a substrate, forming a black matrix in the non-display region, forming a gate line electrically connected to the plurality of pixels and lengthwise extended in a first direction, in the non-display region, and forming a data line electrically connected to the plurality of pixels and lengthwise extended in a second direction intersecting the first direction, in the non-display region. the forming the black matrix in the non-display region defines a first black matrix disposed to lengthwise overlap the gate line and a second black matrix disposed to lengthwise overlap the data line. An aspect ratio of the second black matrix is greater than that of the first black matrix.

This application claims priority to Korean Patent Application No. 10-2015-0095279, filed on Jul. 3, 2015, and all the benefits accruing therefrom under 35 U.S.C. §119, the disclosure of which is incorporated herein in its entirety by reference.

### BACKGROUND

1. Field

One or more exemplary embodiments relate to a manufacturing method of a thin film transistor substrate.

2. Description of the Related Art

According to development of various electronic apparatuses, such as a cell phone, a personal digital assistant (“PDA”), a computer and a large screen television, demands on flat display apparatuses applicable thereto are increasing. Among the flat display apparatuses, a liquid crystal display (“LCD”) has relative advantages of lower power consumption, an easier motion image display and a higher contrast ratio than other display apparatuses.

### SUMMARY

One or more exemplary embodiments include a manufacturing method of a thin film transistor substrate of a display device.

According to one or more exemplary embodiments, a manufacturing method of a thin film transistor substrate includes providing a plurality of pixels each having a display region which realizes color and a non-display region disposed outside the display region and which does not realize color, on a substrate, forming a black matrix in the non-display region, forming a gate line electrically connected to the plurality of pixels and lengthwise extended in a first direction, and forming a data line electrically connected to the plurality of pixels and lengthwise extended in a second direction intersecting the first direction. The forming the black matrix in the non-display region defines a first black matrix disposed to lengthwise overlap the gate line and a second black matrix disposed to lengthwise overlap the data line. An aspect ratio of the second black matrix is greater than that of the first black matrix.

According to one or more exemplary embodiments, the forming the plurality of pixels may include forming in the non-display region, a thin film transistor on the substrate, and forming corresponding to the display region, a color filter on the thin film transistor, a common electrode on the color filter, and a pixel electrode on the common electrode and insulated from the common electrode.

According to one or more exemplary embodiments, the forming the black matrix in the non-display region may include providing a photosensitive resin layer on the common electrode, exposing the photosensitive resin layer on the common electrode using a multi-tone mask, and removing a portion of the exposed photosensitive resin layer. The multi-tone mask may include a first semi-transmitting portion disposed in an area corresponding to each of opposing edges of the second black matrix to be formed and a first light-transmitting portion disposed at an area between the first semi-transmitting portions disposed corresponding to the opposing edges of the second black matrix to be formed.

According to one or more exemplary embodiments, the first light-transmitting portion may include a slit extended along a lengthwise direction of the second black matrix to be formed.

According to one or more exemplary embodiments, a width of the first light-transmitting portion disposed at the area between the first semi-transmitting portions may be about 10% to about 60% of a total width of the second black matrix to be formed.

According to one or more exemplary embodiments, the forming the black matrix in the non-display region may further define a main column spacer as a protrusion of the first black matrix.

According to one or more exemplary embodiments, the forming the black matrix in the non-display region may further define a sub-column spacer as a protrusion of the first black matrix. With respect to the substrate, a maximum height of the sub-column spacer is smaller than a maximum height of the main column spacer.

According to one or more exemplary embodiments, the first black matrix, the second black matrix, the main column spacer, and the sub-column spacer may be simultaneously formed using a same material according to a same process.

According to one or more exemplary embodiments, the multi-tone mask may further include a second light-transmitting portion disposed at an area corresponding to the main column spacer to be formed and a second semi-transmitting portion disposed at an area corresponding to the sub-column spacer to be formed, and the second semi-transmitting may have a light-transmitting ratio between those of the second light-transmitting portion and the first semi-transmitting portion.

According to one or more exemplary embodiments, the color filter may be formed in plural. In the second direction, adjacent color filters are respectively disposed at opposing sides of the gate line, and the first black matrix overlap edge portions of the adjacent color filters disposed at the opposing sides of the gate line. In the first direction, adjacent color filters are respectively disposed at opposing sides of the data line, and the second black matrix may overlap edge portions of the adjacent color filters disposed at the opposing sides of the data line.

According to one or more exemplary embodiments, side portions of the adjacent color filters disposed at the opposing sides of the data line may overlap each other.

### BRIEF DESCRIPTION OF THE DRAWINGS

These and/or other features will become apparent and more readily appreciated from the following description of the exemplary embodiments, taken in conjunction with the accompanying drawings in which:

FIG. 1 is a plan view illustrating an exemplary embodiment of a thin film transistor substrate according to the invention;

FIG. 2 is a cross-sectional view illustrating an exemplary embodiment of the thin film transistor substrate taken along I-I′ of FIG. 1;

FIG. 3 is a cross-sectional view illustrating an exemplary embodiment of the thin film transistor substrate taken along II-II′ of FIG. 1; and

FIGS. 4 to 6 are cross-sectional views illustrating an exemplary embodiment of a manufacturing method of a thin film transistor of FIG. 1.

### DETAILED DESCRIPTION

The exemplary embodiments may have different forms and should not be construed as being limited to the descriptions set forth herein. Accordingly, the exemplary embodiments are merely described below, by referring to the figures, to explain features of the present description.

In the exemplary embodiments, the terms, such as first, second, etc., should not be limited by their terms, but are used to distinguish one element from other element in the exemplary elements. In explaining the invention, detail descriptions on known techniques of related art may be omitted.

Terms used in the present specification are used for explaining a specific exemplary embodiment, not for limiting the invention. The singular terms are intended to include the plural terms as well, unless the context clearly indicates otherwise. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, the size and relative sizes of the elements can be reduced or exaggerated for clarity and for the purpose or description. For example, since the size or thickness of each element is illustrated in the drawings for the purpose of description, the invention is not limited to the drawings illustrating the exemplary embodiments.

In explaining components, when a component is referred to as being “formed on or under another component, it can be directly or indirectly formed on or under the other component. That is, for example, intervening components may be present, and the term “on and under” used herein may be understood as being explained in the drawings.

Reference will now be made in detail to exemplary embodiments, examples of which are illustrated in the accompanying drawings, where like reference numerals refer to like elements throughout.

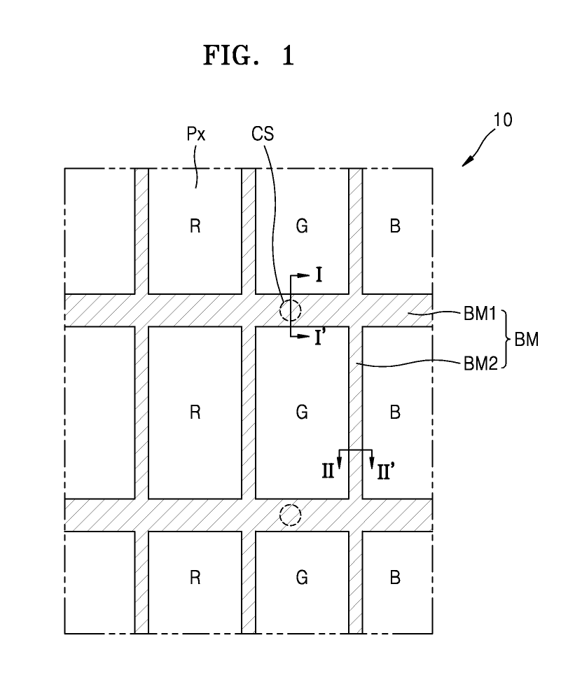

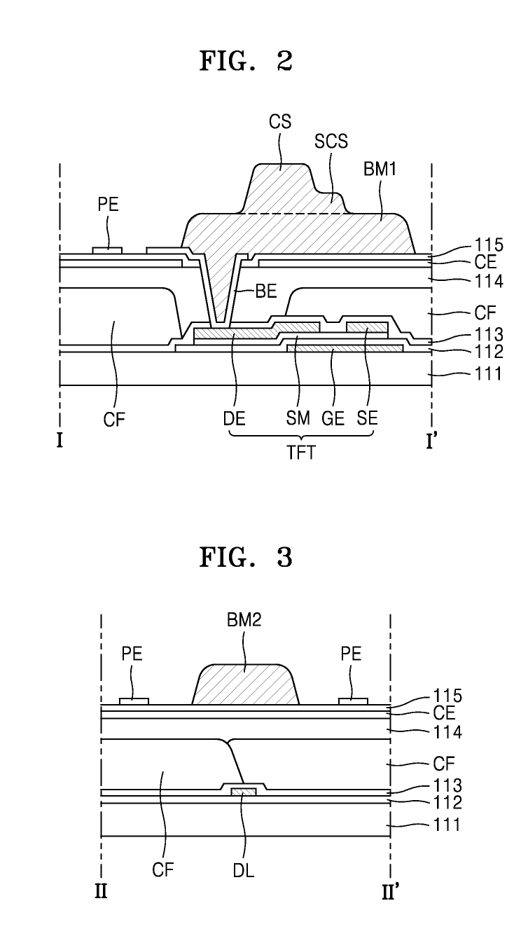

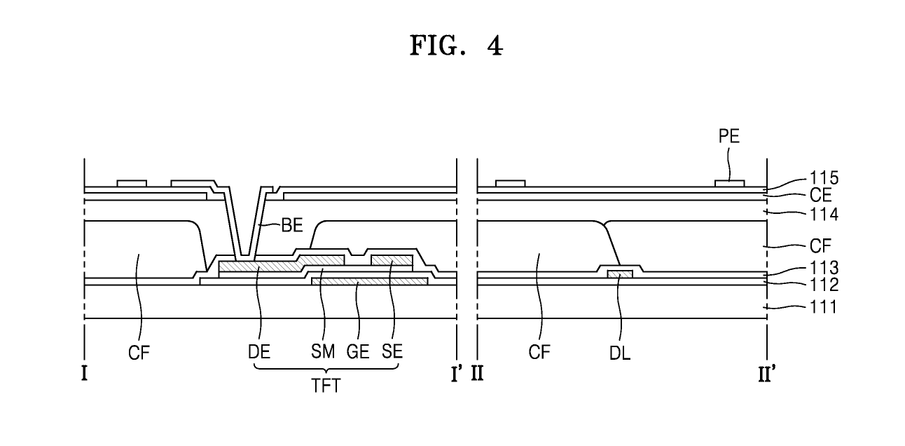

FIG. 1 is a plan view illustrating an exemplary embodiment of a thin film transistor substrate 10 according to the invention, FIG. 2 is a cross-sectional view illustrating the thin film transistor substrate taken along I-I′ of FIG. 1, and FIG. 3 is a cross-sectional view illustrating the thin film transistor substrate taken along II-II′ of FIG. 1.

Referring to FIGS. 1 to 3, the thin film transistor substrate 10 may include a (base) substrate 111, a plurality of pixels Px arranged on the substrate 111, and a black matrix BM.

The substrate 111 may include transparent glass having silicon dioxide (SiO₂) or transparent plastic. A buffer layer (not illustrated) including silicon dioxide (SiO₂) or silicon nitride (SiNx) may be additionally disposed on the substrate 111 to reduce or effectively prevent permeation of an impurity to other elements of the thin film transistor substrate 10.

The plurality of pixels Px each may include a display region in which a color display is realized such as red R, green G and blue B color display, and a non-display region disposed around the display area and in which no display is realized. FIG. 1 illustrates the display region realizing the red R, green G and blue B to be arranged in a lattice pattern. The invention is not limited thereto. The pixels Px may be arranged in various patterns. A pixel Px that realizes a white display such as by white light may be further included.

The non-display region of the pixel Px may include a gate line electrically connected to the plurality of pixels Px. A length of the gate line is extended in a first direction (e.g., horizontal in FIG. 1) to be disposed with respect to the plurality of pixels Px. The non-display region of the pixel Px may further include a data line DL electrically connected to the plurality of pixels Px. A length of the data line is extended in a second direction (e.g., vertical in FIG. 1) perpendicular to the first direction to be disposed with respect to the plurality of pixels Px.

The plurality of pixels Px each may include a thin film transistor TFT, a color filter CF, a common electrode CE and a pixel electrode PE.

The thin film transistor TFT is arranged in the non-display region of the pixel Px and may include a gate electrode GE, a semiconductor layer SM, a source electrode SE and a drain electrode DE.

The gate electrode GE may be connected to the gate line. In an exemplary embodiment, for example, the gate line may be extended in the first direction in the non-display region, and the gate electrode GE may be defined by a widened portion of the gate line protruded in the second direction perpendicular to the first direction. That is, the gate electrode GE and the gate line may integral with each other, and thus, the gate line is not illustrated separately hereinafter. The gate electrode GE and the gate line may be disposed in a same layer of the thin film transistor substrate 10 among layers disposed on the substrate 111.

The gate electrode GE may include at least one metal selected from aluminum (Al), silver (Ag), neodymium (Nd), chromium (Cr), titanium (Ti), tantalum (Ta) and molybdenum (Mo). The gate electrode GE may be a single layer structure or a multilayer structure. In an exemplary embodiment, for example, the gate electrode GE may be a double layer structure with plural metal layers including a first metal layer of chromium (Cr), titanium (Ti), tantalum (Ta) or molybdenum (Mo), and a second metal layer of aluminum (Al) or silver (Ag) having a relatively low resistivity.

A first insulation layer 112 is disposed on the gate electrode GE to insulate the gate electrode GE and the semiconductor layer SM from each other. The first insulation layer 112 may be disposed on an entirety of the substrate 111.

The semiconductor layer SM is disposed on a certain area of the first insulation layer 112. The semiconductor layer SM is arranged to overlap the gate electrode GE and may collectively include an active layer and an ohmic contact layer. In addition, the semiconductor layer SM may include an oxide semiconductor. The oxide semiconductor may include an oxide including at least one element among indium (In), gallium (Ga), zinc (Zn) and tin (Sn). In an exemplary embodiment, for example, the oxide semiconductor may include zinc oxide, tin oxide, indium oxide, indium zinc (In—Zn) oxide, indium tin (In—Sn) oxide, indium gallium zinc (In—Ga—Zn) oxide, indium zinc tin (In—Zn—Sn) oxide, and indium gallium zinc oxide (IGZO) such as indium gallium zinc tin (In—Ga—Zn—Sn) oxide.

The source electrode SE and the drain electrode DE are disposed above the semiconductor layer SM. The source electrode SE and the drain electrode DE are spaced apart from each other to expose a portion of the semiconductor layer SM. The source electrode SE and the drain electrode DE may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu).

The drain electrode DE may be connected to the pixel electrode PE, and the source electrode SE may be connected to the data line DL. The data line DL may be lengthwise extended in the second direction intersecting the first direction in which the gate line extends, to be disposed in the non-display region of the plurality of pixels Px. In an exemplary embodiment, for example, the source electrode SE may be defined by a widened portion of the data line protruded inclined with respect to the second direction. That is, the source electrode SE and the data line may integral with each other.

The source electrode SE, the drain electrode DE and the data line DL may include the same material, and may be disposed in a same layer of the thin film transistor substrate 10 among layers disposed on the substrate 111. A second insulation layer 113 may cover the source electrode SE, the drain electrode DE, the data line DL, and the exposed upper portion of the semiconductor layer SM.

The color filter CF may be disposed on the second insulation layer 113. The color filter CF corresponds to at least the display region of each pixel Px to provide color to the light transmitted at the pixel Px. The color filter CF is provided in plural on the substrate 11. Here, “corresponds to the display region” may mean “disposed and/or formed on the entire display region” and may include “a portion disposed and/or formed on the non-display region.” The color filter CF may be one of a red color filter, a green color filter and a blue color filter but the invention is not limited thereto.

A width of the data line DL and that gate line (or the gate electrode) is respectively taken perpendicular to a length of the data line DL and the gate line. The data line DL has a width smaller than that of the gate line (or the gate electrode GE). Accordingly, the color filters CF disposed at opposing sides of the gate line (or the gate electrode GE) are spaced apart from each other, as illustrated in FIG. 2. However, side portions of the color filters CF disposed at opposing sides of the date line DL may overlap each other, as illustrated in FIG. 3.

A third insulation layer 114 is disposed on the second insulation layer 113 to cover the color filter CF. The third insulation layer 114 is formed on the entire substrate 111.

The common electrode CE may be disposed on the third insulation layer 114. The common electrode CE includes a transparent conductive material and may correspond to the display region of the pixel Px. Here, “correspond to the display region” may mean “disposed and/or formed on the entire display region” and may include “a portion disposed and/or formed on the non-display region.”

In an exemplary embodiment, for example, the common electrode CE may include a transparent conductive metal oxide, such as indium tin oxide (“ITO”), indium zinc oxide (“IZO”) and indium tin zinc oxide (“ITZO”). The common electrode CE may include defined therein an opening at a location which overlaps with a contact hole at which a branch electrode BE (which will be described later) is disposed. In a top plan view, the opening defined in the common electrode CE may be larger than the contact hole at which the branch electrode BE is disposed to reduce or effectively prevent a short circuit between the common electrode CE and the branch electrode BE.

A fourth insulation layer 115 is disposed to cover the common electrode CE and the pixel electrode PE is disposed on the fourth insulation layer 115. The fourth insulation layer 115 insulates the pixel electrode PE and the common electrode CE from each other.

The pixel electrode PE is disposed to correspond to the display region of each pixel Px and is electrically connected to the drain electrode DE of the thin film transistor TFT. Here, “to correspond to the display region” may mean “disposed and/or formed throughout the entire display region” and may include “a portion dispose and/or formed on the non-display region.”

The contact hole is defined in the second insulation layer 113, the third insulation layer 114 and the fourth insulation layer 115 to expose a predetermined portion of the drain electrode DE, and the branch electrode BE branched from and defined by the pixel electrode PE may be connected to the drain electrode DE through the contact hole. The branch electrode BE contacts the drain electrode DE at the contact hole. According to this structure, a data voltage received through the data line DL connected to the source electrode SE is applied to the pixel electrode PE through the drain electrode DE, and a fringe electrical field may be generated between the common electrode CE to which a common voltage is applied and the pixel electrode PE.

The pixel electrode PE and the branch electrode BE defined thereby may include a transparent conductive material. In an exemplary embodiment, for example, the pixel electrode PE and the branch electrode BE may include a transparent conductive metal oxide such as indium tin oxide (“ITO”), indium zinc oxide (“IZO”) and indium tin zinc oxide (“ITZO”).

The black matrix BM is disposed on the non-display region of the plurality of pixels Px. The black matrix BM may include an organic material including carbon black.

The black matrix BM may define a first black matrix BM1 a length of which is extended to overlap the length of the gate line and a second black matrix BM2 a length of which is extended to overlap the length of the data line DL. Since the gate line and the data line DL may intersect each other, the first black matrix BM1 and the second black matrix BM2 may be defined to intersect each other.

The first black matrix BM1 may overlap edge portions of the color filters CF disposed at the opposing sides of the gate line, and the second matrix BM2 may overlap edge portions of color filters CF disposed at the opposing sides of the data line DL. Accordingly, the black matrix BM may reduce or effectively prevent light leakage generated at edge portions of the display region of the pixel Px and color mixing generated at edge portions of the color filters CF.

A main column spacer CS and a sub-column spacer SCS may be disposed on an upper portion of the first black matrix BM1. The main column spacer CS and the sub-column spacer SCS may include the same material as the first black matrix BM1. The black matrix BM may define each of the first black matrix BM1, the main column spacer CS, the sub-column spacer SCS and the second column spacer BM2. The first black matrix BM1 may extend to define each of the main column spacer CS and the sub-column spacer SCS.

The main column spacer CS may maintain a gap between the thin film transistor substrate 10 and an upper display substrate of a display device. A liquid crystal of the display device may be disposed between the thin film transistor substrate 10 and the upper substrate. With reference to the substrate 111 (or the fourth insulating layer 115), a height of the secondary column spacer SCS is disposed at a maximum distance from the substrate 111 between heights at maximum distances of the main column spacer CS and the first black matrix BM1 from the substrate 111. The secondary column spacer SCS assists the main column spacer CS to maintain the gap between the thin film transistor substrate 10 and the upper substrate of the display device.

The main column spacer CS may have various shapes such as a circular or polygon in the top plan view as indicated by the dotted line circle in FIG. 1. The sub-column spacer SCS may be disposed adjacent to the main column spacer CS or may extended lengthwise along a length direction of the first black matrix BM1.

The second black matrix BM2 may include the same material as the first black matrix BM1. The second black matrix BM2 may be disposed to overlap the data line DL to reduce or effectively prevent the light leakage and color mixing at the data line DL disposed in the non-display region of the pixel Px.

Since the data line DL has a width smaller than that of the gate line (or gate electrode GE), a width of the second black matrix BM2 may be smaller than that of the first black matrix BM1. However, with reference to the substrate 111, the second black matrix BM2 may be disposed at a maximum distance from the substrate 111 which is the same as that of the first black matrix BM1 to effectively block light. A thickness of the first black matrix BM1 may be defined from the fourth insulating layer 115, such as to exclude the black matrix BM portion extended into the contact hole. That is, since the width of the second black matrix BM2 is smaller than that of the first black matrix BM1 with maximum distances thereof from the substrate 111 being the same, the second black matrix BM2 may have an aspect ratio larger than an aspect ratio of the first black matrix BM1. Where an aspect ratio typically describes the proportional relationship between width and height, the aspect ratios of the black matrix BM may be defined by the width of the respective portion of the black matrix BM related to the maximum distance thereof from the fourth insulating layer 115.

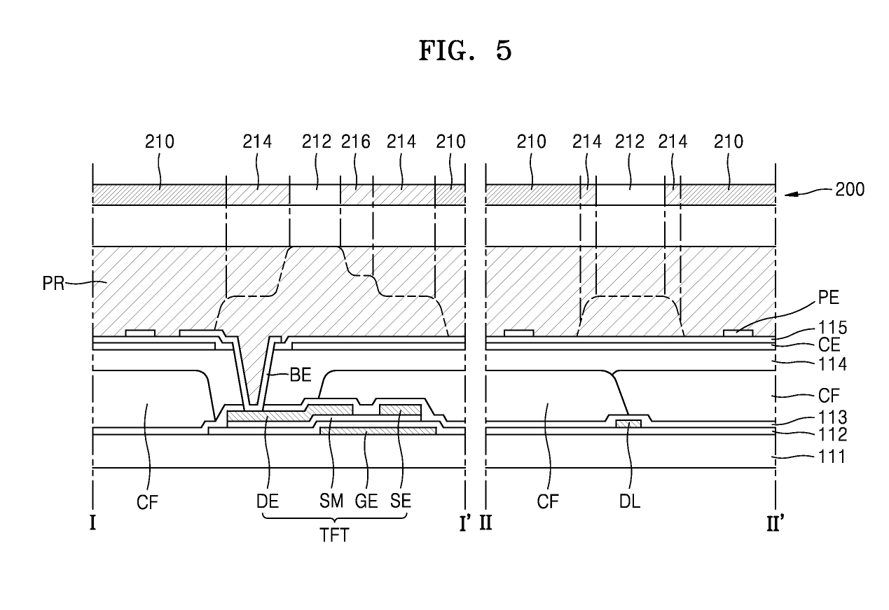

FIGS. 4 to 6 are views illustrating an exemplary embodiment of a manufacturing method of a thin film transistor of FIG. 1. Each of FIGS. 4 to 6 illustrates cross-sections I-I′ and II-II′ of FIG. 1 for the convenience of description.

Referring to FIGS. 1 and 4 to 6, the exemplary embodiment of a manufacturing method of the thin film transistor according to the invention may collectively include operations of preparing the substrate 111, forming on the substrate 111 the plurality of pixels Px each having the display region in which color is realized and the non-display region around the display region and in which color is not realized, and forming the black matrix BM on the non-display region of the plurality of pixels Px.

Referring to FIGS. 1 and 4, the forming the plurality of pixels Px may include forming a thin film transistor TFT on the substrate 111, forming the color filter CF on the thin film transistor TFT, forming the common electrode CE on the color filter CF, and forming the pixel electrode PE on the common electrode CE while being insulated from the common electrode CE, as illustrated in FIG. 4.

The gate electrode GE may be formed in the non-display region of the pixel Px, and the gate electrode GE and the gate line may be simultaneously formed with each other to be disposed in a same layer among layers formed on the substrate 111. In an exemplary embodiment, a length of the gate line is formed to be extended along the first direction (e.g., horizontal in FIG. 1) in the non-display region of the plurality of pixels Px to be connected to a group of pixels Px among the plurality of pixels Px. The gate electrode GE may be defined by an expanded width portion of the gate line at a position corresponding to the respective pixels Px. The expanded width portion of the gate line may protrude in a direction perpendicular to (e.g., vertical in FIG. 1) the first direction.

The first insulation layer 112 is formed on the gate electrode GE, and the semiconductor layer SM is formed on the first insulation layer 112. The first insulation layer 112 may include or be formed of an organic material, an inorganic material or an organic/inorganic composite material. In an exemplary embodiment, for example, the first insulation layer 112 may include silicon nitride SiNx or silicon oxide SiOx, however, the invention is not limited thereto. The semiconductor layer SM is formed to at least partially overlap the gate electrode GE.

The source electrode SE and the drain electrode DE are formed on the first insulation layer 112 to be spaced-apart from each other and expose a portion of the semiconductor layer SM. The data line DL may be simultaneously formed together with the source electrode SE and the drain electrode DE to be disposed in a same layer among layers formed on the substrate 111. A length of the data line DL may be extended along the second direction intersecting the first direction in which the gate line is extended to be connected to a group of pixels Px among the plurality of pixels Px.

The second insulation layer 113 may be formed to cover the source electrode SE, the drain electrode DE and the data line DL. The color filter CF may be formed on the second insulation layer 113 in the display region of the pixels Px. The second insulation layer 113 may be otherwise referred to as a passivation layer and may include an inorganic material such as silicon nitride SiO₂ and/or silicon nitride SiNx.

The color filter CF may be one of a red color filter, a green color filter and a blue color filter according to a corresponding pixel Px. The third insulation layer 114 may be formed on the color filter CF and may include an organic insulation layer including an organic material.

The common electrode CE is formed on the third insulation layer 114, and the pixel electrode PE is formed on the common electrode CE while being insulated from the common electrode CE. The fourth insulation layer 115 may be formed between the common electrode CE and the pixel electrode PE. The fourth insulation layer 115 may include an inorganic insulation layer including an inorganic material.

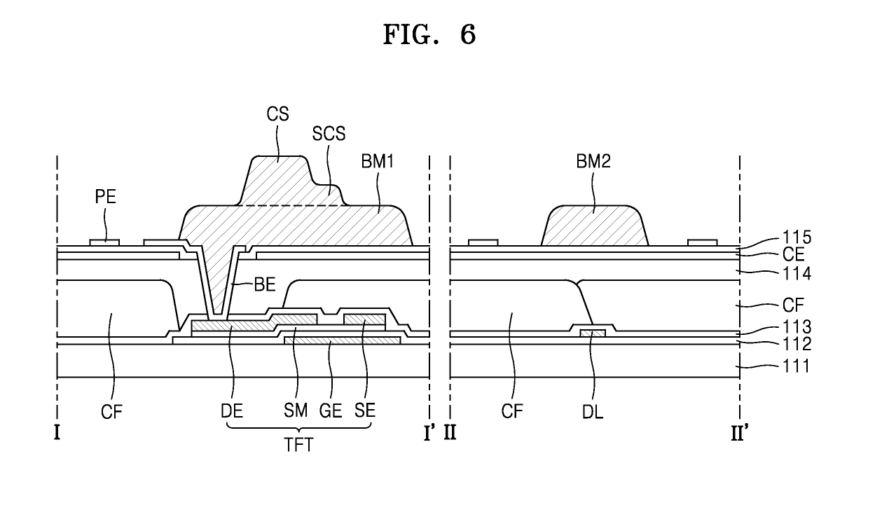

The black matrix BM may formed by using a photolithographic process including forming a photosensitive resin layer PR on the pixel electrode PE, exposing the photosensitive resin layer PR using a multi-tone mask 200, and removing the exposed photosensitive resin layer PR, as illustrated in FIGS. 5 and 6. According to this process, the first black matrix BM1, the main column spacer CS, the sub-column spacer SCS and the second black matrix BM2 may be simultaneously formed using the same material according to the same process. The first black matrix BM1, the main column spacer CS, the sub-column spacer SCS and the second black matrix BM2 are disposed in a same layer of the thin film transistor substrate 10 among layers disposed on the substrate 111.

As one example, the multi-tone mask 200 may include a light-blocking portion 210, a light-transmitting portion 212, a first semi-light-transmitting portion 214 and a second semi-light-transmitting portion 216.

The light-blocking portion 210 may be formed to correspond to an area where the black matrix BM is not formed. The first semi-transmitting portion 214 may be formed to correspond to an area where the first black matrix BM1 and the second black matrix BM2 are formed. The second semi-transmitting portion 216 may have a light transmission ratio between those of the light-transmitting portion 212 and the first semi-transmitting portion 214 and may be formed to correspond to an area where the sub-column spacer SCS is formed.

The light-transmitting portion 212 may be an area where about 100% of light transmits through and may be disposed to correspond to an area where the main column spacer CS as well as a central portion of the second black matrix BM2 are formed.

As described above, since a width of the data line DL is smaller than a width of the gate line (gate electrode GE), a width of the second black matrix BM2 is formed to be smaller than a width of the first black matrix BM1. Accordingly, in a conventional method of manufacturing a thin film transistor substrate, when the first black matrix BM1 and the second black matrix BM2 are simultaneously formed using the same material according to the same process, the second black matrix BM2 may be formed to be thinner than the first black matrix BM1 according to an over-development phenomenon during a developing process of the photosensitive resin layer PR. According to this, light transmits through the second black matrix BM2 to undesirably cause light leakage and color mixture around a boundary of the pixel Px.

However, in one or more exemplary embodiment of a method of manufacturing a thin film transistor substrate according to the invention, when the light-transmitting portion 212 is disposed corresponding to the central portion of the second black matrix BM2 and a first semi-transmitting portion 214 is disposed at opposing sides of the light-transmitting portion 212 corresponding to edge areas of the second black matrix BM2, the amount of exposure light is increased at a central portion of the second black matrix BM2, and thus an over-development phenomenon, in which a thickness of the second black matrix BM2 becomes excessively small, is reduced or effectively prevented during the development of the exposed photosensitive resin layer PR.

Accordingly, since a width of the second black matrix BM2 is formed to be smaller than a width of the first black matrix BM1 owing to a width of the data line DL being smaller than a width of the gate line (or gate electrode GE), the thickness of the second black matrix BM2 can be increased without sacrificing a light transmission rate at display areas of the thin film transistor substrate 10. That is, although the width of the second black matrix BM2 is smaller than the width of the first black matrix BM1, the second black matrix BM2 may be formed to have the same thickness as or similar thickness to the first black matrix BM1, and thus, the aspect ratio of the second black matrix BM2 corresponding to the larger width gate line may be larger than the aspect ratio of the first black matrix BM1 corresponding to the smaller width data line DL. The thicknesses of the first black matrix BM1, the second black matrix BM2, the main column spacer CS and the sub-column spacer SCS may be defined from the fourth insulating layer 115, so as to exclude the black matrix BM portion extended into the contact hole.

In the multi-tone mask 200 corresponding to an area where the second black matrix BM2 is to be formed, a width of the light-transmitting portion 212 disposed between first semi-transmitting portions 214 may be about 10% to about 60% of a total width of the second black matrix BM2 to be formed. When the width of the light-transmitting portion 212 of the multi-tone mask 200 is smaller than about 10% of the total width of the second black matrix BM2 to be formed, the light transmitted through the light-transmitting portion 212 may be diffracted to expose an area of the photosensitive resin layer PR wider than the total width of the second black matrix BM2 to be formed such that the photosensitive resin layer PR at the central portion of the second black matrix BM2 to be formed is not sufficiently exposed to the light and increasing the thickness of the second black matrix BM2 becomes difficult. Conversely, when the width of the light-transmitting portion 212 of the multi-tone mask 200 is greater than about 60% of the total width of the second black matrix BM2 to be formed, the second black matrix BM2 may be formed to have a thickness larger than a thickness of the main column spacer CS according to an over-exposure of the photosensitive resin layer PR at the central portion of the second black matrix BM2 to be formed. Where the thickness of the second black matrix BM2 is larger than the thickness of the main column spacer CS, a liquid crystal margin may be reduced such that a cell gap between the thin film transistor substrate 10 and the upper display substrate is affected and a smear may be generated.

In the multi-tone mask 200, the light-transmitting portion 212 disposed at the central portion between the opposing first semi-transmitting portions 214 corresponding to an area where the second black matrix BM2 is to be formed may have a slit shape of which a length thereof is extended in a lengthwise direction of the second black matrix BM2. The light-transmitting portion 212 disposed at the central portion between the opposing first semi-transmitting portions 214 may be defined by a plurality of openings arranged spaced-apart from each other along the lengthwise direction of the second black matrix BM2.

As described above, a negative type photosensitive resin having a characteristic in which an exposed portion thereof remains during a development process is explained, however, the invention is not limited thereto. In an alternative exemplary embodiment, a positive type photosensitive resin having a characteristic in which an exposed portion thereof is removed during a development process may be used.

It should be understood that exemplary embodiments described herein should be considered in a descriptive sense only and not for purposes of limitation. Descriptions of features within each exemplary embodiment should typically be considered as available for other similar features in other exemplary embodiments.

While one or more exemplary embodiments have been described with reference to the figures, it will be understood by those of ordinary skill in the art that various changes in form and details may be made therein without departing from the spirit and scope as defined by the following claims.

What is claimed is:

1. A manufacturing method of a thin film transistor substrate, the method comprising:
providing a plurality of pixels each having a display region and a non-display region which is outside the display region, on a substrate;
forming a black matrix in the non-display region;
forming a gate line electrically connected to the plurality of pixels and lengthwise extended in a first direction, in the non-display region, and
forming a data line electrically connected to the plurality of pixels and lengthwise extended in a second direction intersecting the first direction, in the non-display region,
wherein
the forming the black matrix in the non-display region defines a first black matrix disposed to lengthwise overlap the gate line and a second black matrix disposed to lengthwise overlap the data line, and
an aspect ratio of the second black matrix is greater than that of the first black matrix.

2. The method of claim 1, wherein the forming the plurality of pixels comprises:
forming in the non-display region, a thin film transistor on the substrate; and
forming corresponding to the display region,
a color filter on the thin film transistor;
a common electrode on the color filter; and
a pixel electrode which is on the common electrode and insulated from the common electrode.

3. The method of claim 2, wherein the forming the black matrix in the non-display region comprises:
providing a photosensitive resin layer on the common electrode;
exposing the photosensitive resin layer on the common electrode using a multi-tone mask; and
removing a portion of the exposed photosensitive resin layer,
wherein the multi-tone mask comprises:
a first semi-transmitting portion disposed at an area corresponding to each of opposing edges of the second black matrix to be formed, and
a first light-transmitting portion disposed at an area between the first semi-transmitting portions disposed corresponding to the opposing edges of the second black matrix to be formed.

4. The method of claim 3, wherein the first light-transmitting portion comprises a slit extended along a lengthwise direction of the second black matrix to be formed.

5. The method of claim 3, wherein a width of the first light-transmitting portion disposed at the area between the first semi-transmitting portions is about 10% to about 60% of a total width of the second black matrix to be formed.

6. The method of claim 3, wherein the forming the black matrix in the non-display region further defines:
a main column spacer as a protrusion of the first black matrix.

7. The method of claim 6, the forming the black matrix in the non-display region further defines:
a sub-column spacer as a protrusion of the first black matrix,
wherein with respect to the substrate, a maximum height of the sub-column spacer is smaller than a maximum height of the main column spacer.

8. The method of claim 7, wherein the first black matrix, the second black matrix, the main column spacer and the sub-column spacer are simultaneously formed using a same material according to a same process.

9. The method of claim 7, wherein
the multi-tone mask further comprises:
a second light-transmitting portion disposed at an area corresponding to the main column spacer to be formed, and
a second semi-transmitting portion disposed at an area corresponding to the sub-column spacer to be formed, and
the second semi-transmitting portion has a light-transmitting ratio between those of the second light-transmitting portion and the first semi-transmitting portion.

10. The method of claim 2, wherein
the color filter is formed in plural,
in the second direction,
adjacent color filters are respectively disposed at opposing sides of the gate line, and
the first black matrix overlaps edge portions of the adjacent color filters disposed at the opposing sides of the gate line, and in the first direction,
adjacent color filters are respectively disposed at opposing sides of the data line, and
the second black matrix overlaps edge portions of the adjacent color filters disposed at the opposing sides of the data line.

11. The method of claim 10, wherein side portions of the adjacent color filters disposed at the opposing sides of the data line overlap each other.

12. The method of claim 11, wherein in the second direction, side portions of the adjacent color filters disposed at the opposing sides of the gate line are spaced apart from each other.

13. The method of claim 1, wherein with respect to the substrate, a maximum height of the first black matrix is the same as a maximum height of the second black matrix.

14. The method of claim 1, wherein a width of the data line in the first direction is less than a width of the gate line in the second direction.

15. The method of claim 14, wherein a width of the second black matrix in the first direction is less than a width of the first black matrix in the second direction.
